(19) United States
(12) Patent Application Publication
(10) Pub. No.: US 2026/0113956 A1
(43) Pub. Date: Apr. 23, 2026

(54) METHOD OF MANUFACTURING SEMICONDUCTOR DEVICE, SEMICONDUCTOR DEVICE, AND PRINTED CIRCUIT BOARD

(71) Applicant: Kioxia Corporation, Tokyo (JP)

(72) Inventors: Yoshiki HORIMATSU, Yokohama Kanagawa (JP); Yorichika BANDO, Fujisawa Kanagawa (JP)

(21) Appl. No.: 19/063,206

(22) Filed: Feb. 25, 2025

(30) Foreign Application Priority Data
Oct. 17, 2024 (JP) 2024-181888

(51) Int. Cl. H10B 80/00; H01L 23/00; H01L 23/495; H01L 25/00; H01L 25/18

(52) U.S. Cl. CPC H10B 80/00; H10W 70/424; H10W 70/442; H10W 90/00; H10W 90/756

(57) ABSTRACT

According to one embodiment, a method of manufacturing a semiconductor device includes: providing a printed circuit board that has a first surface on which a first solder resist is formed and a second surface opposite to the first surface and on which a second solder resist having a first region and a second region is formed, wherein a thickness of the second solder resist in the first region is greater than a thickness of the second solder resist in the second region in a first direction perpendicular to the second surface; placing a semiconductor chip on the first solder resist of the printed circuit board; sealing the semiconductor chip on the printed circuit board; and removing a part of the second solder resist in the first region.

### CROSS-REFERENCE TO RELATED APPLICATION(S)

This application is based upon and claims the benefit of priority from Japanese Patent Application No. 2024-181888, filed Oct. 17, 2024, the entire contents of which are incorporated herein by reference.

### FIELD

Embodiments described herein relate generally to a method of manufacturing a semiconductor device, a semiconductor device, and a printed circuit board.

### BACKGROUND

A semiconductor device having a semiconductor chip provided on a printed circuit board with a solder resist interposed therebetween, is known. In recent years, semiconductor devices have been required to be thinner, but thinner devices are subject to warpage.

### BRIEF DESCRIPTION OF THE DRAWINGS

FIG. 1 is a cross-sectional view illustrating a configuration of a semiconductor device according to an embodiment (an intermediate state before a part of a solder resist is removed).

FIG. 2 is a cross-sectional view illustrating the configuration of the semiconductor device according to the embodiment (in a completed state after a part of the solder resist is removed).

FIG. 3 is a bottom view illustrating the configuration of the semiconductor device according to the embodiment.

FIG. 4 is a bottom view illustrating a configuration in a state where a plurality of printed circuit boards according to the embodiment are framed as one printed circuit board.

FIG. 5 is a cross-sectional view illustrating a configuration of one region of a printed circuit board according to an embodiment.

FIG. 6 is a cross-sectional view illustrating a configuration of another region of a printed circuit board according to the embodiment.

FIG. 7 is a flowchart illustrating a method of manufacturing a semiconductor device according to an embodiment.

FIGS. 8-13 are each a cross-sectional view illustrating a step of manufacturing the semiconductor device according to the embodiment.

FIG. 14 is a flowchart illustrating a method of manufacturing a semiconductor device according to another embodiment.

### DETAILED DESCRIPTION

Embodiments provide a method of manufacturing a semiconductor device, a semiconductor device, and a printed circuit board capable of reducing the warpage of the printed circuit board.

In general, according to one embodiment, a method of manufacturing a semiconductor device includes: providing a printed circuit board that has a first surface on which a first solder resist is formed and a second surface opposite to the first surface and on which a second solder resist having a first region and a second region is formed, wherein a thickness of the second solder resist in the first region is greater than a thickness of the second solder resist in the second region in a first direction perpendicular to the second surface; placing a semiconductor chip on the first solder resist of the printed circuit board; sealing the semiconductor chip on the printed circuit board; and removing a part of the second solder resist in the first region.

According to another embodiment, a semiconductor device includes: a core member that has a first surface and a second surface opposite to the first surface; a first prepreg that is formed on the first surface; a second prepreg that is formed on the second surface and has a third region and a fourth region; a first solder resist that is formed on the first prepreg; a second solder resist that is formed on the second prepreg and has a first region and a second region; a semiconductor chip that is provided on the first solder resist; and a sealing resin that seals the semiconductor chip, wherein the third region is provided at a position at which the third region overlaps with the first region in a first direction perpendicular to the second surface, and the fourth region is provided at a position at which the fourth region overlaps with the second region in the first direction, and wherein the second solder resist in the first region is formed to be thicker in the first direction than the second solder resist in the second region, and a part of the second solder resist is to be removed.

According to another embodiment, a printed circuit board includes: a core material that has a first surface and a second surface opposite to the first surface; a first prepreg that is formed on the first surface; a second prepreg that is formed on the second surface and has a third region and a fourth region; a first solder resist that is formed on a surface of the first prepreg opposite to the first surface; and a second solder resist that is formed on a surface of the second prepreg opposite to the second surface and has a first region and a second region, wherein the third region is provided at a position at which the third region overlaps with the first region in a first direction perpendicular to the second surface, and the fourth region is provided at a position at which the fourth region overlaps with the second region in the first direction, and wherein a thickness of the second solder resist in the first region is greater than a thickness of the second solder resist in the second region, in the first direction.

Hereinafter, embodiments will be described with reference to the drawings.

The drawings hereinafter given for reference are schematic, and the relationship between thickness and planar dimensions, the ratio of thicknesses of layers, and the like may differ from actual ones. Further, between the drawings, some parts may have different dimensional relationships and ratios. In the following description, elements having substantially the same functions and configurations are represented by the same reference numerals and signs. Alphabetical characters following the letters of the reference numerals and signs are used to distinguish between elements having similar configurations and reference numerals including the same letters. In the present specification, a step includes not only one step, but also a combination of the step with other steps and other processes.

First, a first direction, a second direction, and a third direction are defined. The first direction is a direction perpendicular to a first surface 1a of a printed circuit board 1 to be described later. The second and third directions are directions that intersect with (for example, perpendicular to) the first direction. In other words, the second and third directions are directions that are parallel to the first surface 1a of the printed circuit board 1.

### 1. Structure (Configuration)

### 1.1. Semiconductor Device

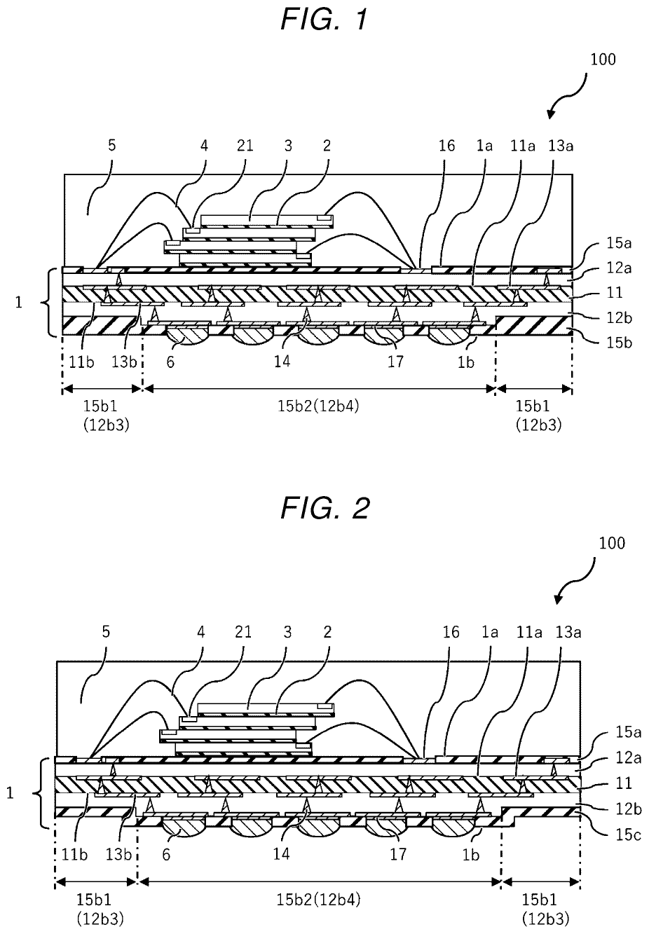

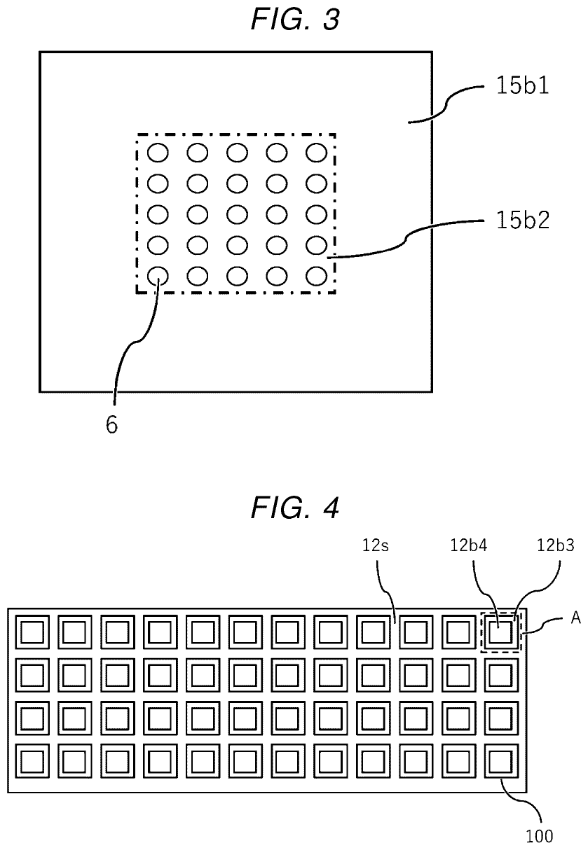

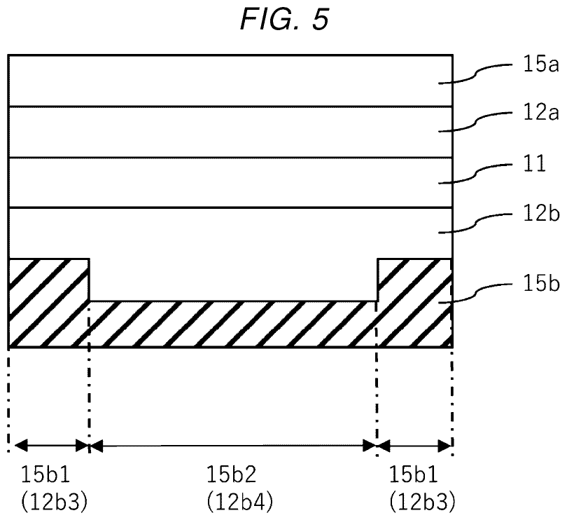

FIG. 1 is a cross-sectional view illustrating a configuration of a semiconductor device 100 according to an embodiment (in an intermediate state). FIG. 2 is a cross-sectional view illustrating a configuration of the semiconductor device 100 according to the embodiment (in a completed state). FIG. 3 is a bottom view of the configuration of the semiconductor device 100 according to the embodiment shown in FIGS. 1 and 2, as viewed from a lower side. FIG. 1 shows the “intermediate state before a part of the second solder resist 15b is removed”. FIG. 2 shows the “completed state where a part of the second solder resist 15b is removed after the intermediate state”. For details of the method of manufacturing the semiconductor device 100, refer to “2. Manufacturing Method” to be described later. As shown in FIG. 1, the semiconductor device 100 includes a printed circuit board 1, an adhesive 2, a stack of semiconductor chips 3, connection members 4, a sealing resin 5, and metal bumps 6.

The printed circuit board 1 includes a core member 11, a first prepreg 12a, a second prepreg 12b, interconnection layers 13a and 13b, vias 14, a first solder resist 15a, second solder resists 15b and 15c, pads 16, and electrodes 17. The printed circuit board 1 has a first surface 1a and a second surface 1b opposite to the first surface 1a. Further, the printed circuit board 1 may have a multilayer wiring structure which is formed by stacking a plurality of interconnection layers and a plurality of insulating layers.

The core member 11 has a third surface 11a and a fourth surface 11b opposite to the third surface 11a. An insulating material such as glass epoxy resin is used for the core member.

The interconnection layer 13a is provided on the third surface 11a of the core member 11. The interconnection layer 13b is provided on the fourth surface 11b of the core member 11. The interconnection layers 13a and 13b are electrically connected through the vias 14. When it is not necessary to distinguish between the interconnection layers 13a and 13b, the interconnection layers 13a and 13b are described as the interconnection layer 13.

The first prepreg 12a is provided on the third surface 11a of the core member 11. The second prepreg 12b is provided on the fourth surface 11b of the core member 11. The second prepreg 12b has a third region 12b3 and a fourth region 12b4. The third region 12b3 is an example of the third region. The fourth region 12b4 is an example of the fourth region. The thickness of the third region 12b3 may be equal to or less than the thickness of the fourth region 12b4, in the first direction. In one embodiment, the thickness ratio of the fourth region 12b4 to the third region 12b3 of the prepreg is, for example, 1.25 or more.

The first solder resist 15a is provided on the first prepreg 12a. The first solder resist 15a covers the first prepreg 12a except for a part corresponding to the pads 16. The second solder resist 15b is provided on the second prepreg 12b. The second solder resist 15b covers the second prepreg 12b except for a part corresponding to the electrodes 17. The second solder resist 15b has a first region 15b1 corresponding to the third region 12b3 of the second prepreg 12b and a second region 15b2 corresponding to the fourth region 12b4 of the second prepreg 12b. A thickness of the second solder resist 15b in the first region 15b1 is equal to or greater than a thickness of the second solder resist 15b in the second region 15b2, in the first direction. In one embodiment, the thickness ratio of the first region 15b1 to the second region 15b2 of the solder resist is, for example, 1.25 or more. The first solder resist 15a electrically insulates the first prepreg 12a to protect the first prepreg 12a.

The pads 16 are provided on the first prepreg 12a. The pads 16 may be a part of the interconnection layer 13a. The pads 16 contain a conductive material such as copper (Cu). The electrodes 17 are provided on the second prepreg 12b. The electrodes 17 may be a part of the interconnection layer 13b. The electrodes 17 contain a conductive material such as copper (Cu). The metal bumps 6 are provided on the electrode 17. The metal bumps 6 are electrically connected to the interconnection layer 13b through the electrodes 17. The metal bumps 6 may be provided on the electrodes 17 after “Step S6 (Step of Removing Part of Second Solder Resist)” to be described later. A conductive material such as solder is used for the metal bumps 6.

The adhesive 2 is a thermosetting resin. The adhesive 2 is, for example, an epoxy resin, a polyimide resin, an acrylic resin, or a resin mixture of these. The adhesive 2 may be, for example, a die attach film (DAF).

The stack of semiconductor chips 3 is provided on the first surface 1a of the printed circuit board 1 with the adhesive 2 interposed therebetween. In addition, the adhesive 2 is provided between the semiconductor chips 3 in the stack. Each semiconductor chip 3 has a pad 21 on the outer periphery of the surface. The pads 16 and 21 are electrically connected through the conductive connection members 4 such as bonding wires. The pads 16 and 21 are connected in a one-to-one manner.

The semiconductor chips 3 may be a semiconductor chip such as a NAND flash memory, but is not limited to the NAND flash memory. For example, any semiconductor chip may be used, which is a memory element such as a dynamic random access memory (DRAM), an arithmetic element such as a microprocessor, a signal processing element, or the like. It should be noted that the semiconductor chips 3 may be provided as a single chip instead of as a plurality of stacked chips.

The sealing resin 5 seals the first surface 1a of the printed circuit board 1, the adhesive 2, the semiconductor chips 3, and the connection members 4. For example, a thermosetting resin such as an epoxy resin is used for the sealing resin 5.

The metal bumps 6 are electrically connected to the interconnection layer 13 through the electrodes 17. A conductive material such as solder is used for the metal bumps 6. As shown in FIG. 2, in the intermediate state of the semiconductor device 100 shown in FIG. 1, a part of the solder resist 15b is removed under predetermined conditions to form the solder resist 15c. As a result, manufacturing of the semiconductor device 100 is completed. The above-mentioned predetermined conditions (such as a location of the part to be removed and an amount of the part to be removed) are selected in the following manner. Samples of individual divided pieces of the semiconductor device are separately provided, measurement tests using a plurality of samples with different conditions such as the location of the part to be removed and the amount of the part to be removed are performed, and conditions for reducing the warpage of the printed circuit board are selected from among the conditions. For details, refer to “2. Manufacturing Method” to be described later. The solder resist 15c refers to the solder resist obtained after a part of the solder resist 15b is removed from the first region 15b1. The solder resist 15c electrically insulates the second prepreg 12b to protect the second prepreg 12b. As shown in FIG. 3, the first region 15b1 of the solder resist 15c surrounds the periphery of the second region 15b2 of the solder resist 15c. In general, a semiconductor device having a printed circuit board has a problem in that the warpage of the printed circuit board increases as the thickness thereof decreases. Returning to the description of FIG. 1, in the semiconductor device 100 according to the embodiment, the thickness of the second solder resist 15b in the first region 15b1 is thicker than the thickness of the second solder resist 15b in the second region 15b2. In addition, a part of the solder resist 15b is removed in the first region 15b1 under the conditions for reducing the warpage of the printed circuit board. Thereby, it is possible to reduce the warpage of the printed circuit board. In other words, the semiconductor device 100 has the solder resist 15b with the thickness capable of reducing the warpage of the printed circuit board. As a result, it is possible to reduce the warpage of the printed circuit board.

### 1.2. Printed Circuit Board

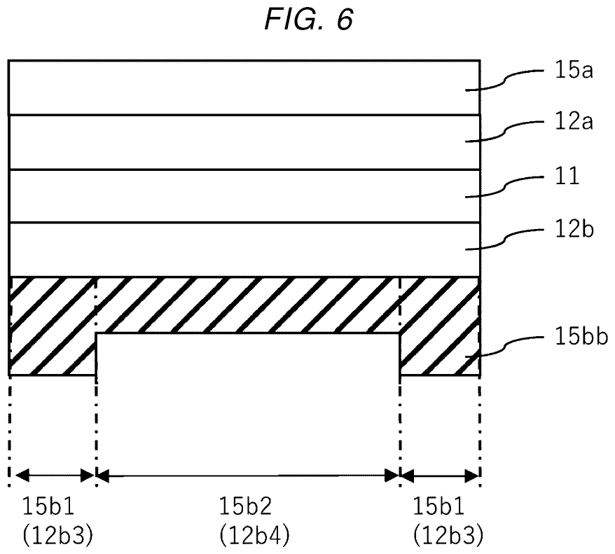

Here, the printed circuit board 1 forming the semiconductor device 100 will be described. FIG. 4 is a bottom view illustrating a configuration of the semiconductor device 100 according to the present embodiment in a state where a plurality of printed circuit boards 1 are collectively framed as one printed circuit board. The prepreg 12b3 is an example of the third region. The prepreg 12b4 is an example of the fourth region. It should be noted that the interconnection layer 13, the vias 14, the solder resist 15, and the electrodes 17 are omitted in FIG. 4. For details of the method of manufacturing the semiconductor device 100 having the printed circuit board 1, refer to “2. Manufacturing Method” to be described later.

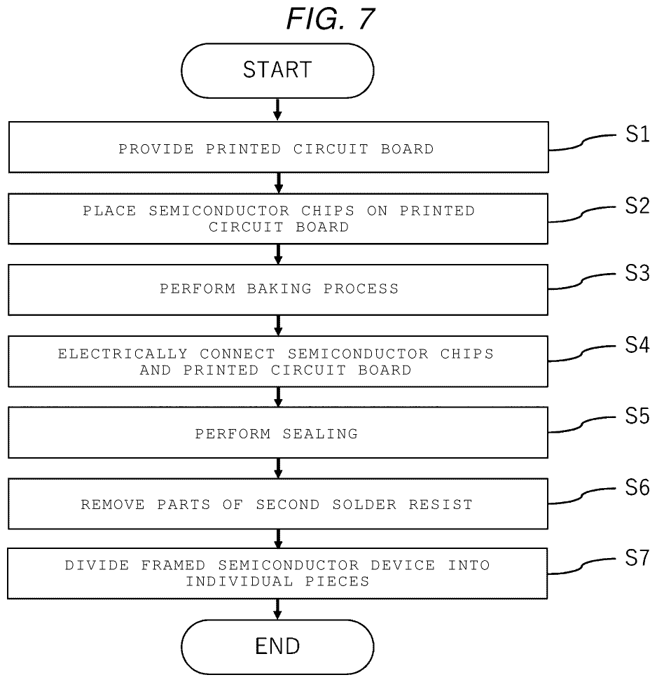

The chip-shaped semiconductor device 100 is obtained by dividing a printed circuit board such as the one shown in FIG. 4 into individual pieces. In the printed circuit board before dividing, a plurality of semiconductor devices 100 are arranged, for example, in a matrix shape. Scribe lines 12s for dividing the semiconductor device 100 into the individual pieces are provided between the individual semiconductor devices 100. FIG. 5 is an example of a cross-sectional view of an enlarged view of a part A in FIG. 4 as viewed from a second direction or the third direction. FIG. 5 is a view in which a part of FIG. 1 is illustrated in a simplified manner. It should be noted that the interconnection layer 13, the vias 14, and the electrodes 17 are omitted in FIG. 5. In the printed circuit board according to the embodiment, the thickness of the second solder resist 15b in the first region 15b1 is greater than the thickness of the second solder resist 15b in the second region 15b2. Therefore, a part of the second solder resist 15b in the first region 15b1 can be removed under conditions in a wide range. Therefore, by removing a part of the second solder resist 15b under conditions for reducing the warpage of the printed circuit board, it is possible to reduce the warpage of the printed circuit board (Effect 1). Further, in the printed circuit board according to the embodiment, the thickness of the second solder resist 15b in the first region 15b1 is greater than the thickness of the first solder resist 15a in the first direction. In the related art, the thicknesses of the first solder resist 15a and the second solder resist 15b provided on both sides of the printed circuit board 1 are substantially the same. Meanwhile, in the method of manufacturing the semiconductor device according to the embodiment, the thicknesses are made different so that they are unbalanced, and then a part of the thicker part is removed to balance the thicknesses. As a result, the warpage of the printed circuit board is reduced. Therefore, it is possible to reduce the warpage of the printed circuit board with high accuracy (Effect 2). Furthermore, in the printed circuit board according to the embodiment, the thickness of the second prepreg 12b in the third region 12b3 is less than the thickness of the second prepreg 12b in the fourth region 12b4. In this state, when the second solder resist 15b is formed on the second prepreg 12b, the thickness of the first region 15b1 of the second solder resist 15b becomes greater than the thickness of the second region 15b2. Consequently, in order to increase the thickness of the first region 15b1 of the second solder resist 15b, it is not necessary to add a step of applying the solder resist. Therefore, it is possible to easily reduce the warpage of the printed circuit board (Effect 3). Moreover, in the printed circuit board according to the embodiment, in a state where a plurality of printed circuit boards 1 are framed as one printed circuit board, the semiconductor chips provided on the respective printed circuit boards 1 are sealed with resin. Then, a part of the thicker part of the second solder resist is removed in a state where the printed circuit boards 1 are still framed. Thereby, it is possible to easily perform the process of reducing the warpage of the printed circuit board (Effect 4).

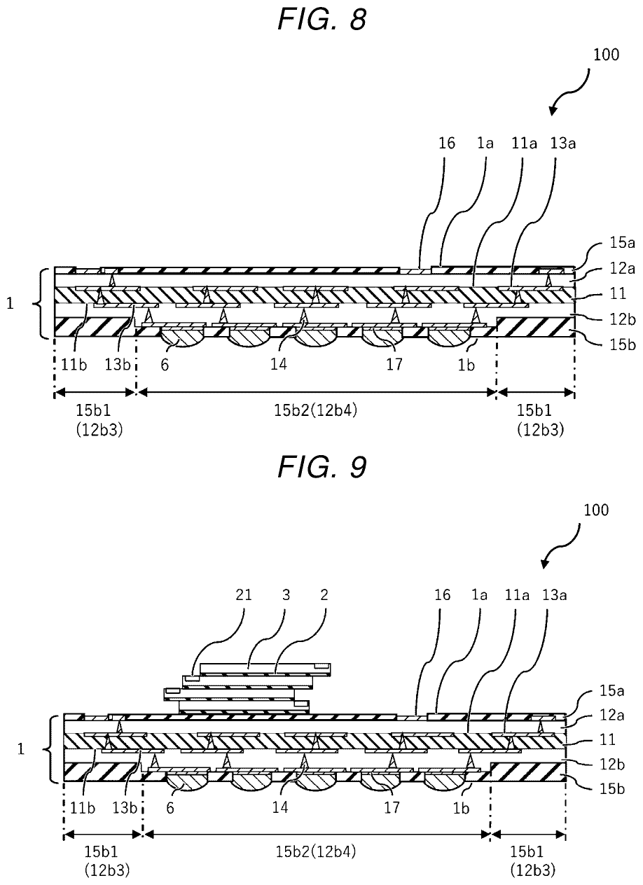

FIG. 6 is an example of a cross-sectional view of an enlarged view of the part A in FIG. 4 as viewed from a second direction or the third direction. It should be noted that the interconnection layer 13, the vias 14, and the electrodes 17 are omitted in FIG. 6. FIG. 6 is different from FIG. 5 in terms of the uniform thickness of the second prepreg 12b and the shape of the second solder resist 15bb provided on the second prepreg 12b. The thickness of the first region 15b1 of the solder resist 15bb is greater than the thickness of the second region 15b2 of the solder resist 15bb in the first direction.

### 2. Manufacturing Method

### 2.1. Method of Manufacturing Semiconductor Device

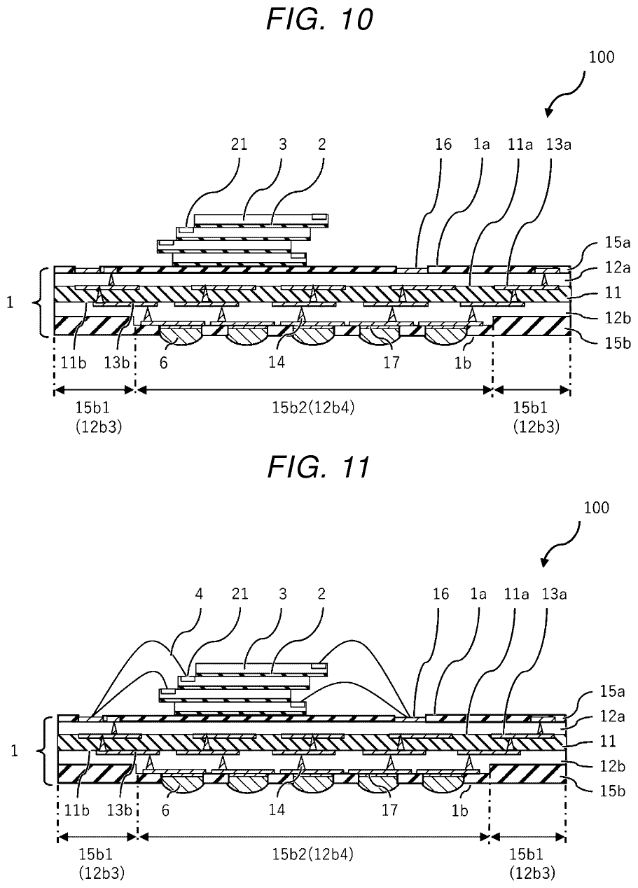

Hereinafter, a method of manufacturing the semiconductor device according to the present embodiment will be described. FIG. 7 is a flowchart showing the method of manufacturing the semiconductor device according to the present embodiment. As shown in FIG. 4, in the present embodiment, the following steps are sequentially performed: a step of providing a printed circuit board (step S1); a step of placing a semiconductor chip on the printed circuit board (step S2); a step of performing baking process (step S3); a step of electrically connecting the semiconductor chip to the printed circuit board (step S4); a step of sealing (step S5); and a step of removing a part of the second solder resist (step S6). Hereinafter, the steps will be described.

### 2.1.1. Step S1 (Step of Providing Printed Circuit Board)

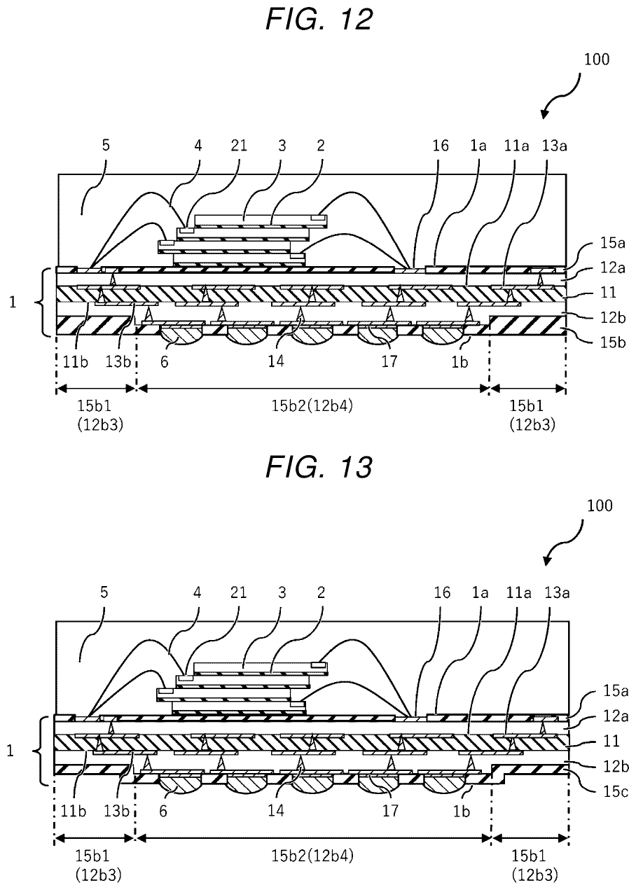

First, the printed circuit board 1 as shown in FIG. 8 is provided. The printed circuit board 1 has the first surface 1a on which the first solder resist 15a is formed and the second surface 1b which faces the first surface 1a and on which the second solder resist 15b having the first region 15b1 and the second region 15b2 is formed. Further, the thickness of the second solder resist 15b in the first region 15b1 is greater than the thickness of the second solder resist 15b in the second region 15b2, in the first direction perpendicular to the second surface 1b. A plurality of printed circuit boards described above are framed to create one printed circuit board. The plurality of printed circuit boards used in Steps S2 to S6 to be described later are framed as one printed circuit board. The framed printed circuit board 1 may be created by a manufacturer of a semiconductor device, but is often created by a manufacturer of a printed circuit board. When the manufacturer of the printed circuit board creates the framed printed circuit board 1, the manufacturer of the semiconductor device obtains the framed printed circuit board 1 from the manufacturer of the printed circuit board, and manufactures the semiconductor device 100 by using the framed printed circuit board 1.

### 2.1.2. Step S2 (Step of Placing the Semiconductor Chips on Printed Circuit Board)

Next, as shown in FIG. 9, the stack of semiconductor chips 3 with the adhesive 2 attached to the rear surface of the stack is placed on the first surface 1a of the printed circuit board 1. Through holes are formed in the core member 11 using a drill or the like. Then, the vias 14 are formed by filling the inside of each through hole with copper or the like. It should be noted that the vias 14 may be formed by plating the side surface of the through hole with copper or the like. Then, the interconnection layer 13 is formed on the core member 11 by the known method. Then, the first prepreg 12a is provided on the third surface 11a of the core member. Then, the solder resist 15a is provided on the first prepreg 12a, and the solder resist 15b is provided on the second prepreg 12b.

### 2.1.3. Step S3 (Step of Baking Process)

Next, as shown in FIG. 10, a baking process is performed to remove moisture and volatile organic substances attached to the printed circuit board 1.

### 2.1.4. Step S4 (Step of Electrically Connecting Semiconductor Chip and Printed Circuit Board)

Next, as shown in FIG. 11, the pads 16 formed on the prepreg 12a and the pads 21 formed on the outer periphery of the surface of the semiconductor chips 3 are electrically connected through the connection members 4.

### 2.1.5. Step S5 (Step of Sealing)

Next, as shown in FIG. 12, the entire surface of the first surface 1a of the printed circuit board 1 is covered with the sealing resin 5 such that the adhesive 2, the semiconductor chips 3, and the connection members 4 are all covered. The sealing resin 5 is cured by a drying step, a thermal curing step, an ultraviolet curing step, and the like. The semiconductor device 100 (intermediate state) according to the embodiment shown in FIG. 1 is manufactured through the above-mentioned steps.

### 2.1.6. Step S6 (Step of Removing Part of Second Solder Resist)

Next, as shown in FIG. 13, a part of the first region 15b1 of the solder resist 15b is removed in accordance with the conditions for removing a part of the solder resist (for details, refer to “2.2. Method of Determining Conditions for Removing Part of Second Solder Resist” to be described later). At this time, the first region 15b1 of the second solder resist 15b is removed through a polishing step or the like. The semiconductor device 100 (completed state) according to the embodiment shown in FIG. 2 is manufactured through the above-mentioned steps (Steps S1 to S6).

2.1.7. Step S7 (Step of Dividing Framed Semiconductor Device into Individual Pieces)

Finally, the framed semiconductor device 100 formed on each printed circuit board is divided into individual pieces to form each semiconductor device 100.

### 2.2. Method of Determining Conditions for Removing Part of Second Solder Resist

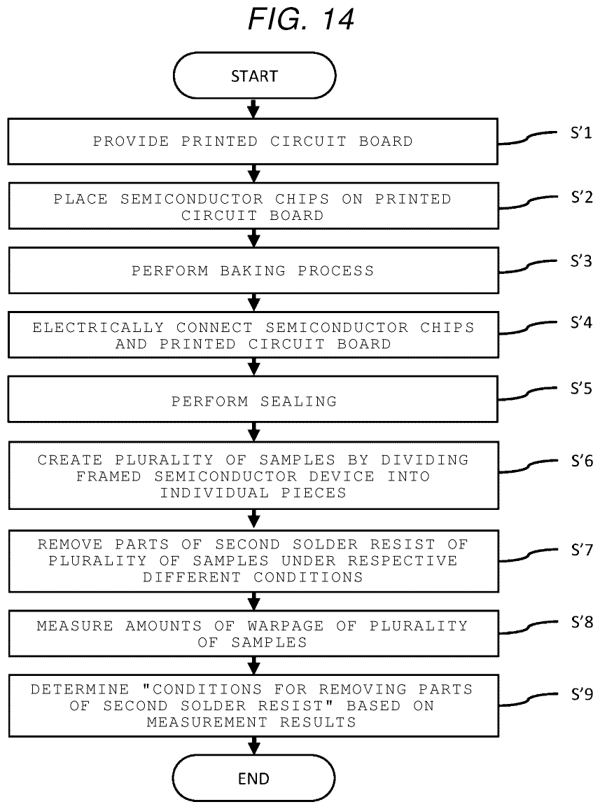

FIG. 14 is a flowchart illustrating a method of determining conditions for removing a part of the second solder resist (step S6) in the manufacturing method according to the embodiment. The method includes: a step of providing a printed circuit board (step S'1); a step of placing the semiconductor chips on the printed circuit board (step S'2); a step of performing the baking process (step S'3); a step of electrically connecting the semiconductor chips and the printed circuit board (step S'4); a step of sealing (step S'5); a step of creating a plurality of samples by dividing into individual pieces (step S'6); a step of removing the solder resist of each of the plurality of samples under a different condition (step S'7); a step of measuring the amounts of warpage of the plurality of samples (step S'8); and a step of determining conditions based on the measurement results (step S'9). The method of determining conditions for removing a part of the solder resist is different from the method of manufacturing the semiconductor device according to the embodiment, in terms of the step of creating the plurality of samples by dividing the printed circuit board on which the semiconductor chip has been sealed, into individual pieces (step S'6) and the subsequent steps. Therefore, the steps up to the step of sealing (Steps S'1 to S'5) will not be described.

### 2.2.1. Step S'6 (Step of Dividing Semiconductor Device Into Individual Pieces to Create Plurality of Samples)

In this step, the framed semiconductor device manufactured in the steps up to step S'5 is divided into individual pieces by a cutting step, creating a plurality of samples.

### 2.2.2. Step S'7 (Step of Removing Solder Resist on Each of Plurality of Samples Under a Different Condition)

In this step, a part of the first region 15b1 of the solder resist 15b of each of the plurality of samples is removed under a different condition (conditions such as the location of the part to be removed and the amount of the part to be removed). By variously modifying the conditions of the location of the part to be removed and the amount of the part of the first region 15b1 to be removed (the thickness of the part to be removed), the amount of warpage of the printed circuit board 1 in each sample becomes different.

### 2.2.3. Step S'8 (Step of Measuring Amounts of Warpage of Plurality of Samples)

In this step, the amount of warpage of each sample is measured after the first region 15b1 of the solder resist 15b is removed under its condition. After the step of resin sealing for the semiconductor device 100 is completed, a temperature cycling test (TCT) is performed to measure the amount of warpage caused by heat.

### 2.2.4. Step S'9 (Step of Determining Conditions Based on Measurement Results)

In this step, the sample having the smallest amount of warpage is specified on the basis of the measurement results of the amounts of warpage of the respective samples. The conditions under which the sample was created (conditions such as the location of the part to be removed and the amount of the part to be removed) are referred to as “removal conditions” in the step of removing a part of the second solder resist (step S6). The “removal conditions” in the step of removing a part of the solder resist (step S5) are determined through the above-mentioned steps (S'1 to S'9). In the method of manufacturing the semiconductor device according to the embodiment, the thickness of the second solder resist 15b in the first region 15b1 is greater than the thickness of the second solder resist 15b in the second region 15b2. Therefore, the part of the second solder resist 15b in the first region 15b1 can be removed under conditions in a wide range. Therefore, by removing a part of the second solder resist 15b under conditions for reducing the warpage of the printed circuit board, it is possible to reduce the warpage of the printed circuit board. Further, in the method of manufacturing the semiconductor device according to the embodiment, the thickness of the second solder resist 15b in the first region 15b1 in the first direction is greater than the thickness of the first solder resist 15a. In the related art, the thicknesses of the second solder resists 15a and 15b provided on both sides of the printed circuit board 1 are substantially the same. Meanwhile, in the method of manufacturing the semiconductor device according to the embodiment, the thicknesses are made different so that they are unbalanced, and then a part of the thicker part is removed to balance the thicknesses. As a result, the warpage of the printed circuit board is reduced. Therefore, it is possible to reduce the warpage of the printed circuit board with high accuracy. Furthermore, in the method of manufacturing the semiconductor device according to the embodiment, in the step of sealing (step S5), the semiconductor chips 3 on the printed circuit board 1 is protected with the sealing resin 5, and then the step of removing a part of the solder resist 15b (step S6) is performed. Therefore, the amount of warpage of the printed circuit board 1 can be easily changed without redesigning the internal structure of the semiconductor device 100 or the printed circuit board 1. Moreover, in the method of manufacturing the semiconductor device according to the embodiment, in the step of sealing (step S5), the semiconductor chips 3 on the printed circuit board 1 is protected with the sealing resin 5, and then the step of removing a part of the solder resist 15b (step S6) is performed. Therefore, when scraps of the solder resist 15b are generated in step S6, the semiconductor chips 3 are protected with the sealing resin 5. Otherwise, the scraps of the solder resist 15b generated in the removal step may become attached to the semiconductor chips 3 to cause defects in the semiconductor device 100. In addition, in the method of manufacturing the semiconductor device according to the embodiment, the thickness of the second prepreg 12b in the third region 12b3 is less than the thickness of the second prepreg 12b in the fourth region 12b4. In this state, when the second solder resist 15b is formed on the second prepreg 12b, the thickness of the first region 15b1 of the second solder resist 15b becomes greater than the thickness of the second region 15b2. Consequently, in order to increase the thickness of the first region 15b1 of the second solder resist 15b, it is not necessary to add a process of applying the solder resist. Therefore, it is possible to easily reduce the warpage of the printed circuit board. Furthermore, in the method of manufacturing the semiconductor device according to the embodiment, in a state where a plurality of printed circuit boards 1 are framed as one printed circuit board, the semiconductor chips provided on the respective printed circuit boards 1 are sealed with resin. Then, a part of the thicker part of the second solder resist is removed in a state where the printed circuit boards 1 are still framed. Thereby, it is possible to easily perform the process of reducing the warpage of the printed circuit board.

### 3. Effects

According to at least one of the above-mentioned embodiments of the semiconductor device, the printed circuit board, and the method of manufacturing the semiconductor device, the thickness of the second solder resist in the first region is greater than the thickness of the second solder resist in the second region. Accordingly, by removing a part of the second solder resist in the first region, it is possible to reduce the warpage of the printed circuit board.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a semiconductor device, comprising:
(a) providing a printed circuit board that has a first surface on which a first solder resist is formed and a second surface opposite to the first surface and on which a second solder resist having a first region and a second region is formed, wherein a thickness of the second solder resist in the first region is greater than a thickness of the second solder resist in the second region in a first direction perpendicular to the second surface;
(b) placing a semiconductor chip on the first solder resist of the printed circuit board;
(c) sealing the semiconductor chip on the printed circuit board; and
(d) removing a part of the second solder resist in the first region.

2. The method of manufacturing the semiconductor device according to claim 1,
wherein a condition for removing the part of the second solder resist in the first region is determined by
creating a plurality of samples by executing steps (a), (b), and (c),
removing a part of the second solder resist in the first region of each of the plurality of samples under different conditions,
after the removing, measuring an amount of warpage of the printed circuit board of each of the plurality of samples under the different conditions, and
determining the condition for executing (d) on the basis of the measured amount of the warpage of the printed circuit board of each of the plurality of samples.

3. The method of manufacturing the semiconductor device according to claim 2,
wherein the condition specifies a location of the part of the second solder resist to be removed, and an amount of the part to be removed.

4. The method of manufacturing the semiconductor device according to claim 1, further comprising:
after removing the part of the second solder resist, forming metal bumps on the second surface.

5. The method of manufacturing the semiconductor device according to claim 1,
wherein the printed circuit board is one of a plurality of printed circuit boards that are framed as one printed circuit board.

6. The method of manufacturing the semiconductor device according to claim 1,
wherein the thickness of the second solder resist in the first region in the first direction is greater than a thickness of the first solder resist.

7. The method of manufacturing the semiconductor device according to claim 1,
wherein the printed circuit board includes
a core member that has a third surface and a fourth surface opposite to the third surface,
a first prepreg that is formed on the third surface, and
a second prepreg that is formed on the fourth surface and has a third region and a fourth region,
wherein the first surface is a surface of the first prepreg, and the second surface is a surface of the second prepreg,
wherein the third region is provided at a position at which the third region overlaps with the first region in the first direction, and the fourth region is provided at a position at which the fourth region overlaps with the second region in the first direction, and
wherein a thickness of the second prepreg in the third region is less than a thickness of the second prepreg in the fourth region, in the first direction.

8. A semiconductor device comprising:
a core member that has a first surface and a second surface opposite to the first surface;
a first prepreg that is formed on the first surface;
a second prepreg that is formed on the second surface and has a third region and a fourth region;
a first solder resist that is formed on the first prepreg;
a second solder resist that is formed on the second prepreg and has a first region and a second region;
a semiconductor chip that is provided on the first solder resist; and
a sealing resin that seals the semiconductor chip,
wherein the third region is provided at a position at which the third region overlaps with the first region in a first direction perpendicular to the second surface, and the fourth region is provided at a position at which the fourth region overlaps with the second region in the first direction, and
wherein the second solder resist in the first region is formed to be thicker in the first direction than the second solder resist in the second region, and a part of the second solder resist is to be removed.

9. The semiconductor device according to claim 8,
wherein a thickness of the second prepreg in the third region is less than a thickness of the second prepreg in the fourth region, in the first direction.

10. The semiconductor device according to claim 8,
wherein the core member, the first prepreg, and the second prepreg form a printed circuit board.

11. A printed circuit board comprising:
a core material that has a first surface and a second surface opposite to the first surface;
a first prepreg that is formed on the first surface;
a second prepreg that is formed on the second surface and has a third region and a fourth region;
a first solder resist that is formed on a surface of the first prepreg opposite to the first surface; and
a second solder resist that is formed on a surface of the second prepreg opposite to the second surface and has a first region and a second region,
wherein the third region is provided at a position at which the third region overlaps with the first region in a first direction perpendicular to the second surface, and the fourth region is provided at a position at which the fourth region overlaps with the second region in the first direction, and
wherein a thickness of the second solder resist in the first region is greater than a thickness of the second solder resist in the second region, in the first direction.

12. The printed circuit board according to claim 11,
wherein a part of the second solder resist in the first region is removable.

13. The printed circuit board according to claim 11,
wherein the thickness of the second prepreg in the third region is less than the thickness of the second prepreg in the fourth region, in a first direction perpendicular to the second surface.

14. A printed circuit board frame comprising:
a plurality of the printed circuit boards according to claim 11 that are arranged in a matrix form.
